(19) United States
(12) Patent Application Publication
(10) Pub. No.: US 2018/0144962 A1
(43) Pub. Date: May 24, 2018

(54) WAFER SUSCEPTOR

(71) Applicant: GlobalWafers Co., Ltd., Hsinchu (TW)

(72) Inventors: Tang-Chi Lin, Hsinchu (TW); Chun-I Fan, Hsinchu (TW); Man-Hsuan Lin, Hsinchu (TW); Wen-Ching Hsu, Hsinchu (TW)

(73) Assignee: GlobalWafers Co., Ltd., Hsinchu (TW)

(21) Appl. No.: 15/790,034

(22) Filed: Oct. 22, 2017

(30) Foreign Application Priority Data
Nov. 21, 2016 (TW) 105217776

(51) Int. Cl. H01L 21/673; H01L 21/687

(52) U.S. Cl. CPC H01L 21/67309; H01L 21/687

(57) ABSTRACT

A wafer susceptor includes a main plate, a plurality of minor plates, and a plurality of plugs. The main plate has a plurality of first notches. The minor plates are respectively disposed in the first notches, and each of the minor plates has a second notch carrying a wafer and an engaging surface of inclination engaged with a side surface of the first notch. A first angle of 20 degrees to 45 degrees is included between the engaging surface of inclination and a horizontal plane. The second notch has a flat side corresponding to a flat of the wafer. An eave portion is disposed on the flat side. The plugs are respectively located between the main plate and the minor plates and are configured to fix the minor plates.

### CROSS-REFERENCE TO RELATED APPLICATION

This application claims the priority benefit of Taiwan application no. 105217776 filed on Nov. 21, 2016. The entirety of the above-mentioned patent application is hereby incorporated by reference herein and made a part of this specification.

### BACKGROUND OF THE INVENTION

### 1. Field of the Invention

The invention relates to a susceptor. More particularly, the invention relates to a wafer susceptor.

### 2. Description of Related Art

Generally, in a chemical vapor deposition (CVD) device used for epitaxial growth of semiconductor manufacturing engineering, a heat source and rotating mechanism are provided under a wafer, and a back-side heating method is used for supplying uniform process gases from above.

In order to achieve uniform film forming on the wafer, an epitaxial reaction is generally performed under high-speed rotation. Nevertheless, an inner edge of the wafer may easily float and drift away caused by a centrifugal force during rotation. Accordingly, the wafer is unable to be maintained at a stable state, and an effect of uniform film forming is thus unable to be achieved.

Moreover, in existing technologies, the wafer is directly carried in a notch on a wafer susceptor, and thus, there is room for improvement to load and unload the wafer more conveniently. In addition, the wafer is not heated evenly as the wafer drifts away from the susceptor.

On the other hand, in epitaxial growth of chemical vapor deposition, the problem about secondary defects such as slip lines and high stress concentration area in the grown epitaxial layer has no favorable solutions yet. The slip lines and the high stress concentration area are generated owing to a variety of factors possibly resulted from co-acting between a mechanical stress and a thermal stress. Specifically, the co-acting may be generated by the mechanical stress caused by mechanical damage and breakage in mechanical processing of the wafer before epitaxy and the thermal stress generated by uneven temperatures on a polishing surface in chemical-mechanical polishing and a greater temperature gradient during high-temperature epitaxy. When a total stress is greater than a critical stress of a crystal slip line triggered by an epitaxial temperature, the slip lines are generated. When the total stress is high but does not exceed the critical stress of the crystal slip line triggered by the epitaxial temperature, the high stress concentration area is generated.

### SUMMARY OF THE INVENTION

The invention provides a wafer susceptor for preventing an inner edge of a wafer from drifting away easily caused by a centrifugal force when rotating, thereby heating the wafer evenly and accordingly realizing the forming of uniform film effectively.

The invention further provides a wafer susceptor capable of prohibiting occurrence of slip lines and a high stress concentration area for increasing film forming quality.

The invention yet further provides a wafer susceptor in which the wafer can be loaded and unloaded more conveniently and can be picked up easily.

A wafer susceptor provided by one embodiment of the invention includes a mother plate, a plurality of minor plates, and a plurality of plugs. The main plate has a plurality of first notches. The minor plates are respectively disposed in the first notches, each of the minor plates has a second notch carrying a wafer and an engaging surface of inclination engaged with a side surface of the first notch. Here, a first angle of 20 degrees to 45 degrees is included between the engaging surface of inclination and a horizontal plane, the second notch has a flat side corresponding to a flat of the wafer, and an eave portion is disposed on the flat side of the second notch. The plugs are respectively located between the main plate and the minor plates and are configured to fix the minor plates.

A wafer susceptor provided by another embodiment of the invention includes a plurality of minor plates, the plurality of minor plates is characterized that each of the minor plates has a second notch carrying a wafer and an engaging surface of inclination, wherein a first angle of 20 degrees to 45 degrees is included between the engaging surface of inclination and a horizontal plane, the second notch has a flat side corresponding to a flat of the wafer, and an eave portion is disposed on the flat side of the second notch.

In an embodiment of the invention, a second angle of 0 degree to 5 degrees is included between a bottom surface of the second notch and a bottom surface of the minor plate in a normal line direction of the flat side.

In an embodiment of the invention, a third angle of 0 degree to 90 degrees is included between the flat side of the second notch and a baseline passing through a center of the wafer and a center of the main plate.

In an embodiment of the invention, the second angle and the flat side are located at a same side.

In an embodiment of the invention, the second angle and an opposite side of the flat side are located at a same side.

In an embodiment of the invention, the second angle is 0 degree to 1 degree.

In an embodiment of the invention, the second angle is 0 degree to 0.5 degree.

In an embodiment of the invention, the second angle is 0.5 degree, and the third angle is 45 degrees.

In an embodiment of the invention, at least one of the plugs is disposed to fix between the main plate and the minor plate, and the at least one of the plugs is disposed on a downstream side in a rotation direction of the main plate.

In an embodiment of the invention, the eave portion is further disposed on a portion other than the flat side.

As described above, according to the embodiments of the invention, in the normal line direction of the flat side, the second angle of 0 degree to 5 degrees is included between the bottom surface of the second notch and the bottom surface of the minor plate, and the first angle of 20 degrees to 45 degrees is included between the engaging surface of inclination and the horizontal plane. Therefore, it can be ensured that the wafer is tightly attached with the minor plate, and the minor plate is tightly attached with the main plate, and that the wafer is heated evenly so as to achieve uniform film forming effectively.

In addition, through the design of the main plate and the minor plates in the embodiments of the invention, the wafer can be loaded and unloaded more conveniently. Moreover, as the wafer is carried in the minor plate, under the circumstance of wafer transfer, the wafer can be picked up more conveniently.

To make the above features and advantages of the invention more comprehensible, several embodiments accompanied with drawings are described in detail as follows. Nevertheless, the invention may be embodied in many different forms and should not be construed as limited to the embodiments set forth herein. For the purpose of clear illustration, some parts of the drawings (e.g. angles) may be exaggerated and are not illustrated according to the practical scale. Moreover, the same reference numerals in the drawings are used to represent the same elements, and thus, descriptions of the same reference numerals are omitted.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic diagram of a wafer susceptor according to an embodiment of the invention.

FIG. 1B is a cross-sectional view taken along the line segment I-I′ in FIG. 1A.

FIG. 1C is an enlarged view of the B area of FIG. 1B.

FIG. 1D is an enlarged view of the C area of FIG. 1B.

FIG. 1E is an enlarged view after the minor plates carrying the wafers are combined with the main plate in the A area of FIG. 1A.

FIG. 2 is a schematic diagram of a first minor plate design according to an embodiment of the invention.

FIG. 3A is a schematic diagram of a second minor plate design according to an embodiment of the invention.

FIG. 3B is a cross-sectional view taken along the line segment I-I′ in FIG. 3A.

FIG. 4A is a schematic diagram of a third minor plate design according to an embodiment of the invention.

FIG. 4B is a cross-sectional view taken along the line segment I-I′ in FIG. 4A.

FIG. 5A is a schematic diagram of a fourth minor plate design according to an embodiment of the invention.

FIG. 5B is a cross-sectional view taken along the line segment I-I′ in FIG. 5A.

FIG. 6A is a schematic diagram of a fifth minor plate design according to an embodiment of the invention.

FIG. 6B is a cross-sectional view taken along the line segment I-I′ in FIG. 6A.

### DESCRIPTION OF THE EMBODIMENTS

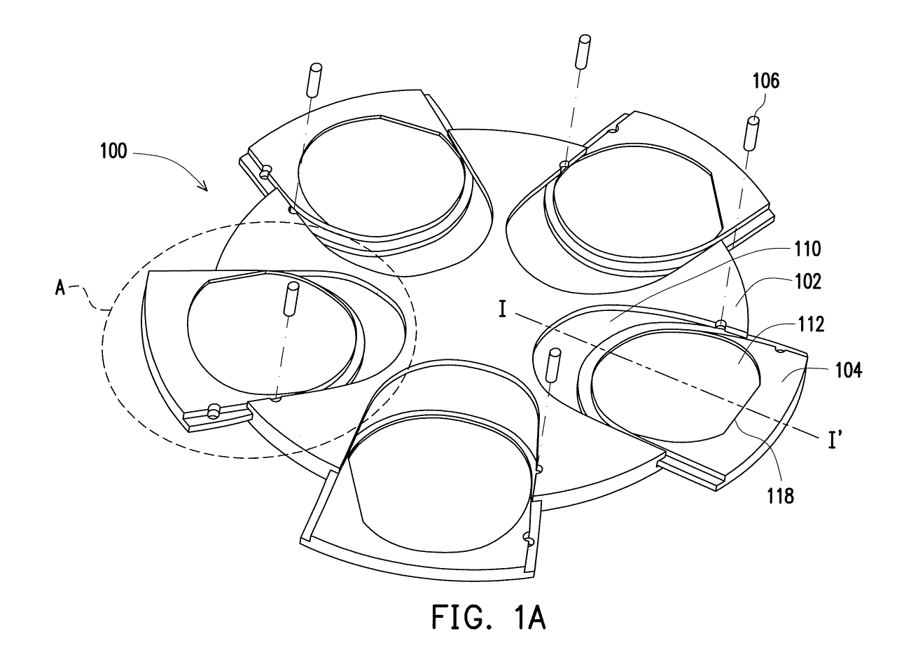

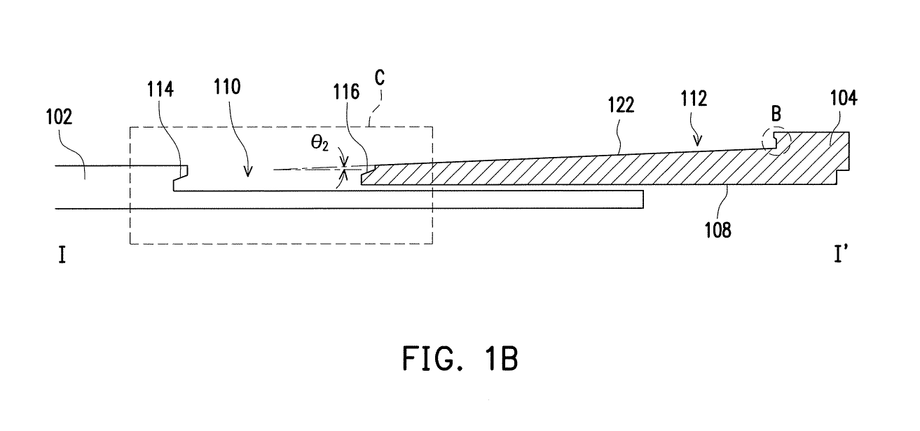

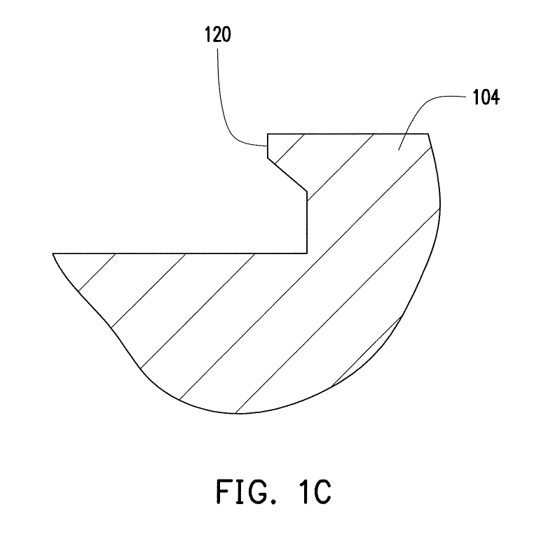

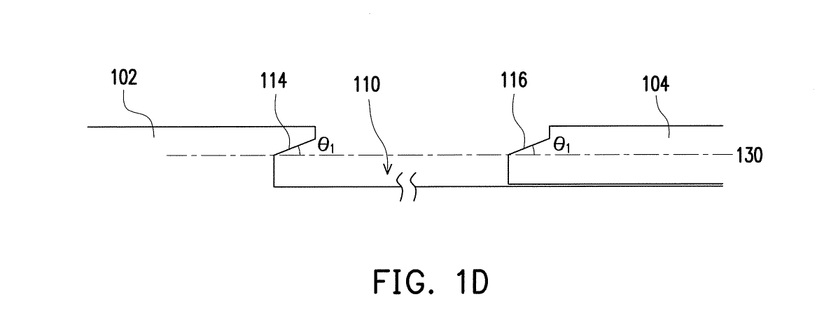

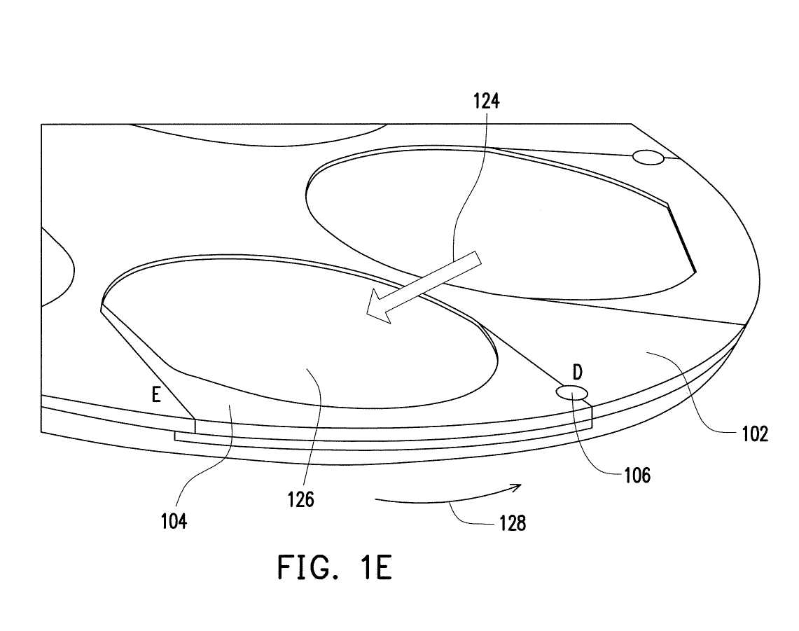

FIG. 1A is a schematic diagram of a wafer susceptor according to an embodiment of the invention.

Referring to FIG. 1A, a wafer susceptor 100 of the embodiments of the invention includes a main plate 102, a plurality of minor plates 104, and a plurality of plugs 106. A center of the wafer susceptor 100 acts as a basis, such that the wafer susceptor 100 may rotate in a clockwise direction or in a counter-clockwise direction.

FIG. 1B is a cross-sectional view taken along the line segment I-I′ in FIG. 1A. FIG. 1C is an enlarged view of the B area of FIG. 1B. FIG. 1D is an enlarged view of the C area of FIG. 1B. FIG. 1E is an enlarged view after the minor plates carrying the wafers are combined with the main plate in the A area of FIG. 1A.

Referring to FIG. 1A and FIG. 1B, the main plate 102 has a plurality of first notches 110. The minor plates 104 are respectively disposed in the first notches 110, and each of the minor plates 104 has a second notch 112 carrying a wafer and an engaging surface of inclination 116 engaged with a side surface 114 of the first notch 110. A size of the wafer to be carried is not particularly limited and can be 4-inch, 6-inch, or other general wafer sizes. Practically, the wafer is first placed in the second notch 112 of the minor plate 104, and the minor plate 104 carrying the wafer is inserted into the first notch 110 of the main plate 102 and then is fixed by the plug 106.

Referring to FIG. 1A, FIG. 1B, and FIG. 1C, in the present embodiment, the second notch 112 has a flat side 118 corresponding to a flat of the wafer. An eave portion 120 (illustrated in FIG. 1C) is disposed on the flat side 118 of the second notch 112, such that the wafer is ensured to be fixed and held in the second notch 112 when carrying the wafer. Nevertheless, the invention is not limited thereto, and in the present embodiment, the eave portion 120 may be further disposed a portion other than the flat side 118. As such, practically, an exposed portion of the wafer on the wafer susceptor 100 is slightly less than the wafer itself.

Referring to FIG. 1D, a first angle θ₁ of 20 degrees to 45 degrees is included between the engaging surface of inclination 116 of the minor plate 104 and a horizontal plane 130. From another aspect, the side surface 114 of the first notch 110 also has an engaging surface of inclination, and the first angle θ₁ of 20 degrees to 45 degrees is thus included between the side surface 114 and the horizontal plane 130. Specifically, the first angle θ₁ is an angle included between the engaging surfaces of inclination and the horizontal plane 130, such that, under high-speed rotation, the minor plate 104 can be pressed and tightly attached with the main plate 102 through a component force of a centrifugal force. As such, a flying-off phenomenon is prevented and at the same time, heat originated from the main plate 102 is evenly transferred to the miner plate 104, and that, the wafer carried in the minor plate 104 is heated evenly. On the contrary, if the first angle θ₁ is greater than 45 degrees, the component force generated is not strong enough to press the minor plate 104, and that the flying-off phenomenon can still occur.

Referring to FIG. 1A, FIG. 1B, and FIG. 1E, in the present embodiment, in a normal line (e.g., the line segment I-I′ of FIG. 1A) direction of the flat side 118, a second angle θ₂ (shown in FIG. 1B) of 0 degree to 5 degrees is included between a bottom surface 122 of the second notch 112 and a bottom surface 108 of the minor plate 104. As such, after the minor plate 104 carrying the wafer and the main plate 102 are combined (as shown in FIG. 1E), under high-speed rotation, a wafer 126 can be tightly attached with the minor plate 104 through a pressure generated by an airflow 124 on the wafer 126. Accordingly, the wafer 126 drifting away from the minor plate 104 can be effectively prevented, so uniform film formation can be effectively realized. Besides, in terms of uniformity of film-forming, in order to enable airflow of epitaxy to be distributed evenly on a surface of the wafer 126, the second angle θ₂ is preferably to be 0 degree to 1 degree and more preferably to be 0 degree to 0.5 degree. Accordingly, a sectional difference between the wafer 126 and the minor plate 104 is decreased to prevent that airflow of epitaxy cannot be in good contact with the wafer 126 due to the sectional difference.

Referring again to FIG. 1E, in the present embodiment, the plugs 106 are respectively located between the main plate 102 and the minor plates 104 and are configured to fix the minor plates 104. Specifically, at least one of the plugs 106 is disposed to fix between the main plate 102 and the minor plate 104, but the invention is not limited thereto. Here, for the convenience of picking up, one plug 106 is preferably to be used to fix between the main plate 102 and the minor plate 104. When only one plug 106 is used to fix between the main plate 102 and the minor plate 104, the plug 106 is preferably disposed on a downstream side in a rotation direction of the main plate 102. FIG. 1E is taken as an example, and a rotation direction 128 of the main plate 102 rotates in the counter-clockwise direction. Under such a circumstance, the plug 106 is preferably disposed on a downstream side D of the rotation direction 128 of the main plate 102, rather than being disposed on an upstream side E of the rotation direction 128 of the main plate 102. If the plug 106 is disposed on the upstream side E of the rotation direction 128 of the main plate 102, the minor plate 104 and the main plate 102 are fixed by the plug 106, as such, the first angle θ₁ of 20 degrees to 45 degrees included between the engaging surface of inclination and the horizontal plane 130 is unable to function effectively when rotating.

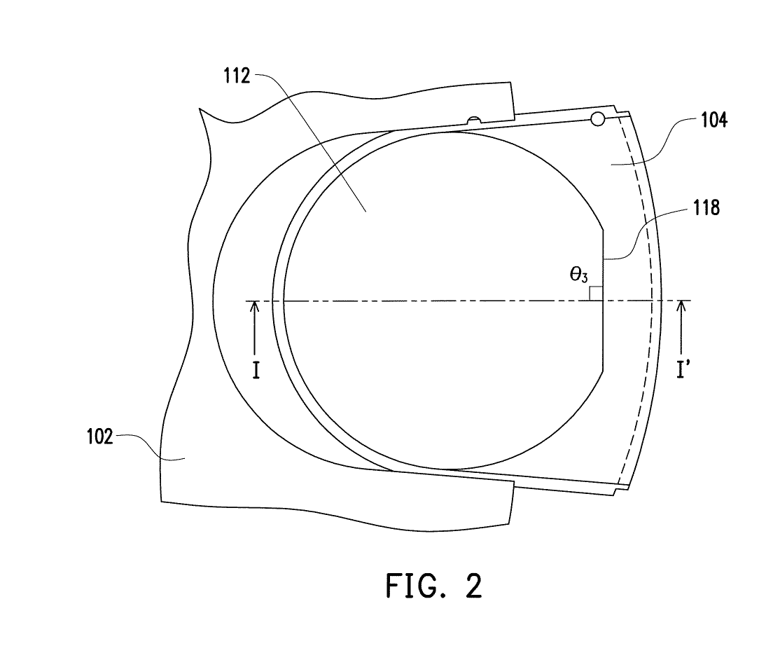

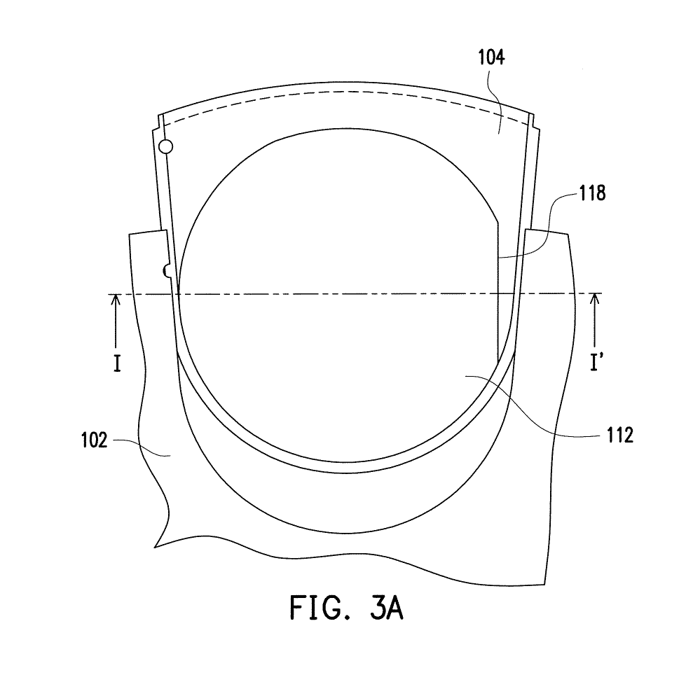

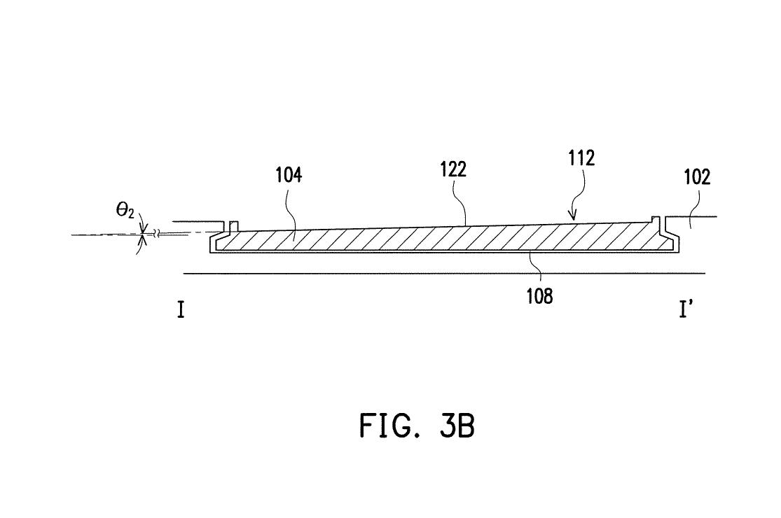

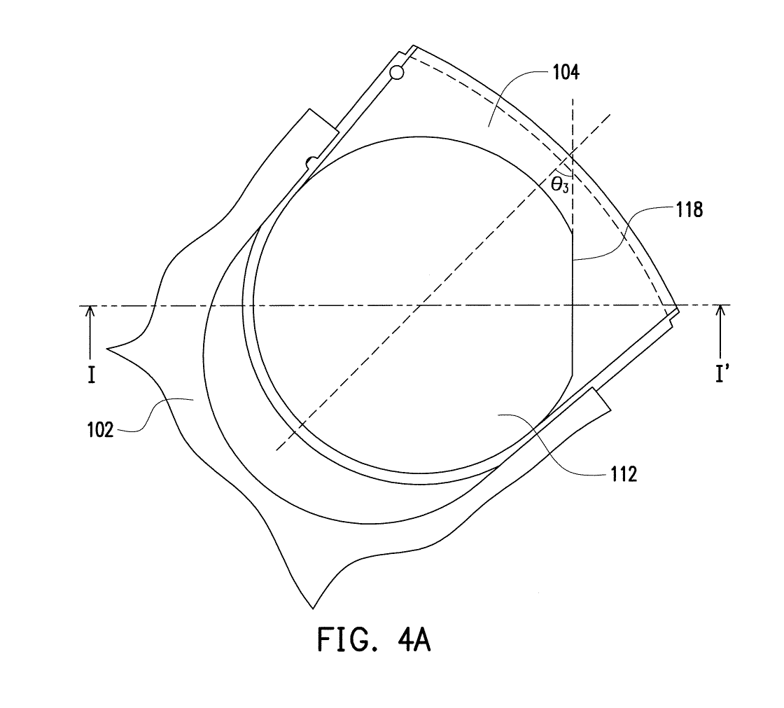

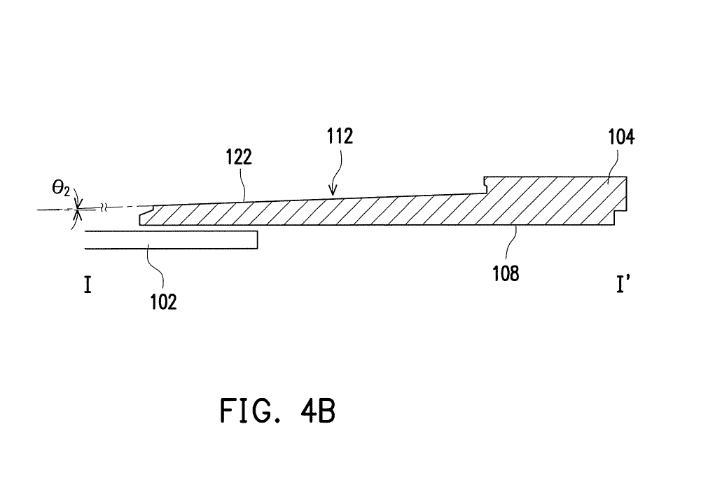

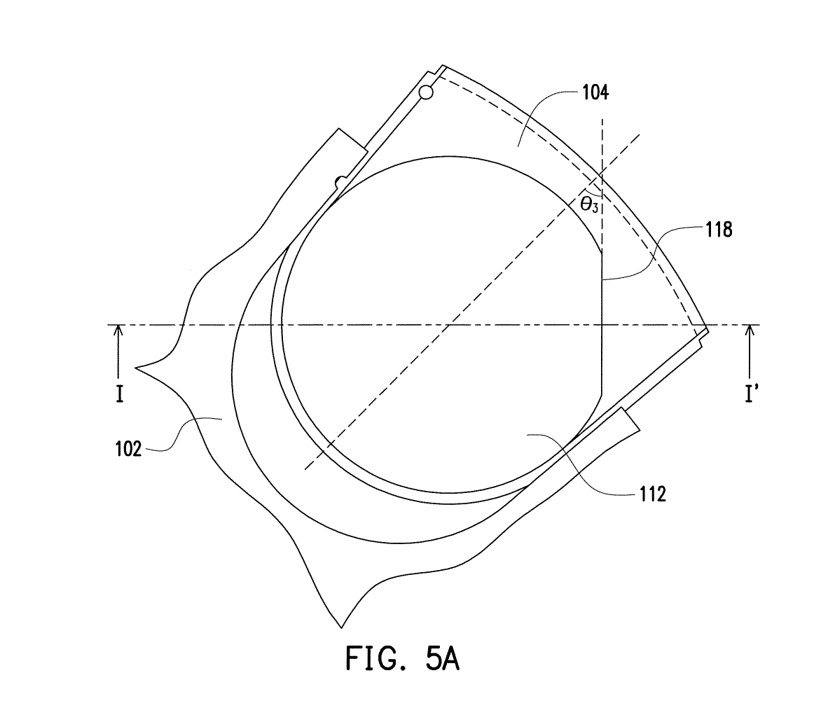

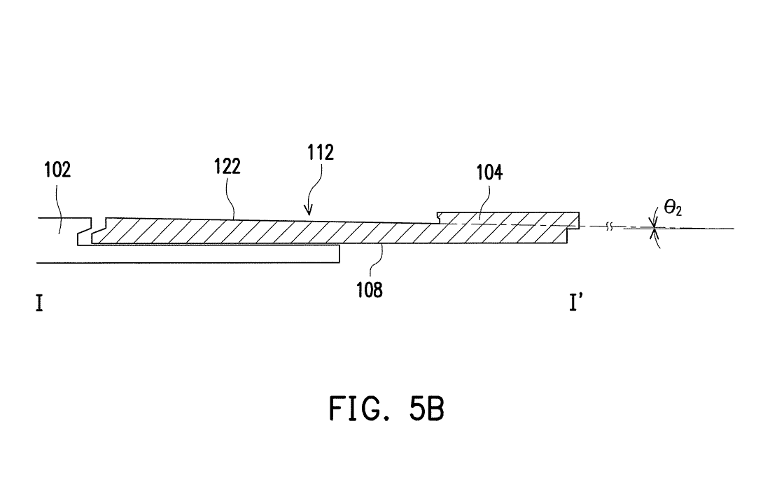

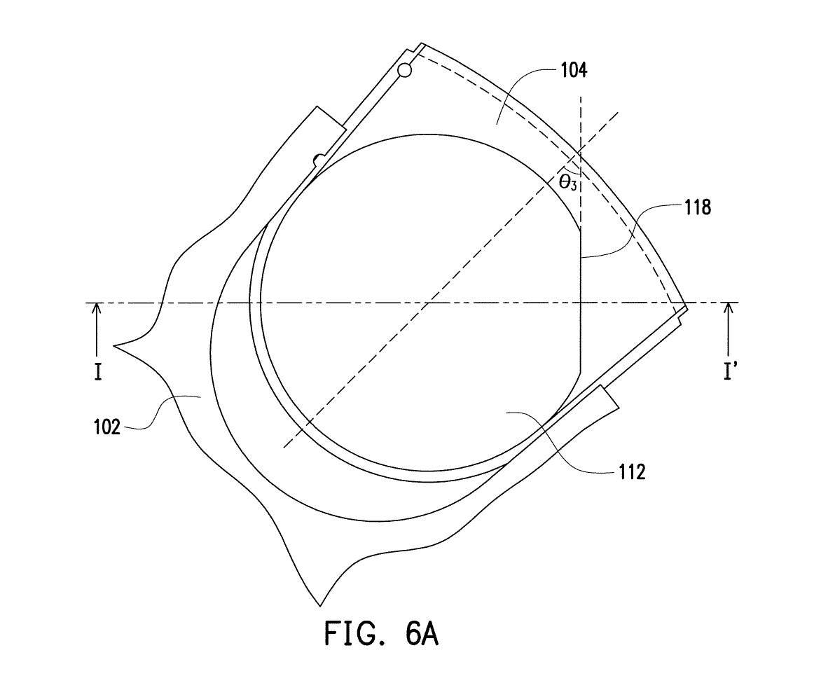

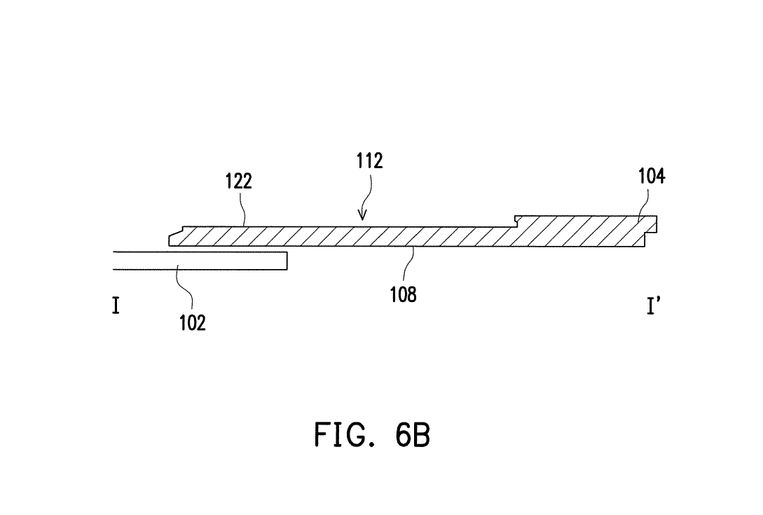

Next, referring to FIG. 1A, FIG. 2, FIG. 3A, FIG. 4A, FIG. 5A, and FIG. 6A, FIG. 1A is a schematic diagram of a wafer susceptor according to an embodiment of the invention. FIG. 2, FIG. 3A, FIG. 4A, FIG. 5A, and FIG. 6A are schematic diagrams of a first to a fifth minor plate designs according to an embodiment of the invention.

First, referring to FIG. 1A, although five minor plates 104 are illustrated on the main plate 102 in FIG. 1A, the invention is not limited thereto, and a number of the minor plates 104 can be added or reduced according to actual requirements. Moreover, in FIG. 1A, five types of arrangements of the minor plates are schematically illustrated, but the invention is not limited thereto, and the types of arrangements of the minor plates may be adjusted according to actual requirements. In the present embodiment, a third angle θ₃ (not shown) of 0 degree to 90 degrees is included between the flat side 118 of the second notch 112 and a baseline passing through a center of the wafer and a center of the main plate.

A first to a fifth minor plate designs of FIG. 2, FIG. 3A, FIG. 4A, FIG. 5A, and FIG. 6A according to an embodiment of the invention are specifically described as follows.

First, FIG. 2 is a schematic diagram of a first minor plate design according to an embodiment of the invention. Here, the third angle θ₃ of 90 degrees is included between the flat side 118 of the second notch 112 and the baseline passing through the center of the wafer and the center of the main plate 102. FIG. 3A is a schematic diagram of a second minor plate design according to an embodiment of the invention. Here, the third angle θ₃ (not shown) of 0 degree is included between the flat side 118 of the second notch 112 and the baseline passing through the center of the wafer and the center of the main plate 102, meaning that the flat side 118 is parallel to the baseline passing through the center of the wafer and the center of the main plate. FIG. 4A to FIG. 6A are schematic diagrams of a third to a fifth minor plate designs according to an embodiment of the invention. Here, the third angle θ₃ of 45 degrees is included between the flat side 118 of the second notch 112 and the baseline passing through the center of the wafer and the center of the main plate 102.

It can be seen that from FIG. 2, FIG. 3A, FIG. 4A, FIG. 5A, and FIG. 6A, locations of the flat side 118 are all directed outward based on the center of the main plate 102, such that, under high-speed rotation, it can prevent from generating a single point of stress concentration caused by the centrifugal force, thereby avoiding the occurrence of slip lines.

FIG. 1B, FIG. 3B, FIG. 4B, FIG. 5B, and FIG. 6B are respectively cross-sectional views taken along the line segment I-I′ in FIG. 1A, FIG. 3A, FIG. 4A, FIG. 5A, and FIG. 6A. Here, FIG. 1B is also a cross-sectional view taken along the line segment I-I′ in FIG. 2.

In the present embodiment, the second angle θ₂ and the flat side 118 can be located on a same side, or the second angle θ₂ and an opposite side of the flat side 118 can be located on the same side.

Referring to FIG. 2 and FIG. 1B, in the schematic diagram of the first minor plate design illustrated in FIG. 2 according to an embodiment of the invention, not only the third angle θ₃ of 90 degrees is included between the flat side 118 of the second notch 112 and the baseline passing through the center of the wafer and the center of the main plate 102, as shown in FIG. 1B, in the normal line direction (as shown by the line segment I-I′) of the flat side 118, the second angle θ₂ of, for example, 0.5 degree is also included between the bottom surface 122 of the second notch 112 and the bottom surface 108 of the minor plate 104. Moreover, the second angle θ₂ and the opposite side of the flat side 118 are located on the same side.

Referring to FIG. 3A and FIG. 3B, in the schematic diagram of the second minor plate design illustrated in FIG. 3A according to an embodiment of the invention, not only the third angle θ₃ of 0 degrees is included between the flat side 118 of the second notch 112 and the baseline passing through the center of the wafer and the center of the main plate 102, as shown in FIG. 3B, in the normal line direction (as shown by the line segment I-I′) of the flat side 118, the second angle θ₂ of, for example, 0.5 degree is also included between the bottom surface 122 of the second notch 112 and the bottom surface 108 of the minor plate 104. Moreover, the second angle θ₂ and the opposite side of the flat side 118 are located on the same side.

Referring to FIG. 4A and FIG. 4B, in the schematic diagram of the third minor plate design illustrated in FIG. 4A according to an embodiment of the invention, not only the third angle θ₃ of 45 degrees is between the flat side 118 of the second notch 112 and the baseline passing through the center of the wafer and the center of the main plate 102, as shown in FIG. 4B, in the normal line direction (as shown by the line segment I-I′) of the flat side 118, the second angle θ₂ of, for example, 0.5 degree is also included between the bottom surface 122 of the second notch 112 and the bottom surface 108 of the minor plate 104. Moreover, the second angle θ₂ and the opposite side of the flat side 118 are located on the same side.

Referring to FIG. 5A and FIG. 5B, in the schematic diagram of the fourth minor plate design illustrated in FIG. 5A according to an embodiment of the invention, not only the third angle θ₃ of 45 degrees is included between the flat side 118 of the second notch 112 and the baseline passing through the center of the wafer and the center of the main plate 102, as shown in FIG. 5B, in the normal line direction (as shown by the line segment I-I′) of the flat side 118, the second angle θ2 of, for example, 0.5 degree is also included between the bottom surface 122 of the second notch 112 and the bottom surface 108 of the minor plate 104. Moreover, the second angle θ₂ and the flat side 118 are located on the same side.

Referring to FIG. 6A and FIG. 6B, in the schematic diagram of the fifth minor plate design in FIG. 6A according to an embodiment of the invention, the third angle θ₃ of 45 degrees is included between the flat side 118 of the second notch 112 and the baseline passing through the center of the wafer and the center of the main plate 102. Moreover, as shown in FIG. 6B, in the normal line direction (e.g., as shown by the line segment I-I′) of the flat side 118, the bottom surface 122 of the second notch 112 is not inclined relative to the bottom surface 108 of the minor plate 104 (parallel to each other), meaning that the second angle θ₂ is 0 degree.

In view of the foregoing, according to the invention, in the normal line direction of the flat side, the second angle of 0 degree to 5 degrees is included between the bottom surface of the second notch and the bottom surface of the minor plate, and a first angle of 20 degrees to 45 degrees is included between the engaging surface of inclination and the horizontal plane. It can be ensured that the wafer is tightly attached with the minor plate, and the minor plate is tightly attached with the main plate, and that the wafer is heated evenly. Hence, uniform film forming is effectively realized.

In addition, the flat side is disposed facing the outer side of the wafer susceptor, the second defect is less likely to occur, and thus, the slip line and the high stress concentration area are prohibited from generating. Furthermore, through the design of the main plate and the minor plate in the embodiments of the invention, the wafer can be loaded and unloaded more conveniently. Moreover, as the wafer is carried in the minor plate, the wafer can be picked up more easily in the case of wafer transfer.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A wafer susceptor, comprising:
a main plate, having a plurality of first notches;
a plurality of minor plates respectively disposed in the first notches, each of the minor plates has a second notch carrying a wafer and an engaging surface of inclination engaged with a side surface of the first notch, wherein a first angle of 20 degrees to 45 degrees is included between the engaging surface of inclination and a horizontal plane, the second notch has a flat side corresponding to a flat of the wafer, and an eave portion is disposed on the flat side of the second notch; and
a plurality of plugs respectively located between the main plate and the minor plates and configured to fix the minor plates.

2. The wafer susceptor as claimed in claim 1, wherein a second angle of 0 degree to 5 degrees is included between a bottom surface of the second notch and a bottom surface of the minor plate in a normal line direction of the flat side.

3. The wafer susceptor as claimed in claim 1, wherein a third angle of 0 degree to 90 degrees is included between the flat side of the second notch and a baseline passing through a center of the wafer and a center of the main plate.

4. The wafer susceptor as claimed in claim 2, wherein the second angle and the flat side are located at a same side.

5. The wafer susceptor as claimed in claim 4, wherein the second angle is 0 degree to 1 degree.

6. The wafer susceptor as claimed in claim 4, wherein the second angle is 0 degree to 0.5 degree.

7. The wafer susceptor as claimed in claim 2, wherein the second angle and an opposite side of the flat side are located at a same side.

8. The wafer susceptor as claimed in claim 7, wherein the second angle is 0 degree to 1 degree.

9. The wafer susceptor as claimed in claim 7, wherein the second angle is 0 degree to 0.5 degree.

10. The wafer susceptor as claimed in claim 1, wherein a second angle of 0.5 degree is included between a bottom surface of the second notch and a bottom surface of the minor plate in a normal line direction of the flat side, and a third angle of 45 degrees is included between the flat side of the second notch and a baseline passing through a center of the wafer and a center of the main plate.

11. The wafer susceptor as claimed in claim 1, wherein at least one of the plugs is disposed to fix between the main plate and the minor plate, and the at least one of the plugs is disposed on a downstream side in a rotation direction of the main plate.

12. The wafer susceptor as claimed in claim 1, wherein the eave portion is further disposed on a portion other than the flat side.

13. A wafer susceptor, comprising a plurality of minor plates, the plurality of minor plates is characterized that:
each of the minor plates has a second notch carrying a wafer and an engaging surface of inclination, wherein a first angle of 20 degrees to 45 degrees is included between the engaging surface of inclination and a horizontal plane, the second notch has a flat side corresponding to a flat of the wafer, and an eave portion is disposed on the flat side of the second notch.

14. The wafer susceptor as claimed in claim 13, wherein a second angle of 0 degree to 5 degrees is included between a bottom surface of the second notch and a bottom surface of the minor plate in a normal line direction of the flat side.

15. The wafer susceptor as claimed in claim 14, wherein the second angle is 0 degrees to 1 degree.

16. The wafer susceptor as claimed in claim 15, wherein the second angle is 0 degree to 0.5 degree.

17. The wafer susceptor as claimed in claim 14, wherein the second angle and the flat side are located at a same side.

18. The wafer susceptor as claimed in claim 14, wherein the second angle and an opposite side of the flat side are located at a same side.

19. The wafer susceptor as claimed in claim 13, wherein the cave portion is further disposed on a portion other than the flat side.
